(19) United States
(12) Patent Application Publication
(10) Pub. No.: US 2002/0149914 A1
(43) Pub. Date: Oct. 17, 2002

(54) Flexible board and information processor

(76) Inventors: Akio Karasawa, Nagano (JP); Shigemitsu Toda, Tokyo (JP); Taketo Wako, Tokyo (JP); Atsuyuki Takai, Nagano (JP)

Correspondence Address: William S Frommer, Frommer Lawrence & Haug, 745 Fifth Avenue, New York, NY, 10151, US

(21) Appl. No.: 10/031,845

(22) PCT Filed: May 25, 2001
(86) PCT No.: PCT/JP01/04415

(30) Foreign Application Priority Data
May 26, 2000 (JP) 2000-156259

(51) Int. Cl. H05K 1/00; G06F 1/16

(52) U.S. Cl. 361/749; 349/52; 361/681

(57) ABSTRACT

A flexible substrate on which a large number of sorts of LCDs can be installed quickly and inexpensively. On loading on a video controller, a connector 21 is electrically connected to first and second contacts of the video controller. The connector 21 is wired so that, if a wiring 31-1 is cut-out and severed along with the end of the flexible printed wiring board 11, the first and second contacts of the video controller are not in electrically connected state.

### TECHNICAL FIELD

This invention relates to a flexible substrate and to an information processing apparatus. More particularly, it relates to a flexible substrate and to an information processing apparatus in which a pre-set ID (identification) may be set in a control circuit.

### BACKGROUND ART

In a notebook type personal computer, PDA (personal digital assistant) or a portable telephone set, liquid crystal display devices, referred to below as liquid crystal displays (LCDs), with variable display screen sizes or resolutions, are extensively used.

A variety of notebook personal computers, carrying LCDs with different sizes of the display screens, that is screen sizes with 13, 14 or 15 inches, even with the use of the same casing or the same mother board, or LCDs having different resolutions, such as 1024×768 dots or 1280×1024 dots, with the same picture size, are on sale.

The LCDs of difference machine types differ in the size of the phosphor tubes enclosed, so that, even if the signals fed are the same, the display brightness differs from one LCD to another. So, the personal computers carrying the LCDs are adjusted prior to shipment as to the LCD brightness so that a picture will be displayed thereon to the same display brightness.

For facilitating this adjustment, a panel ID for specifying the LCD type is now in use. When a panel ID is input to a video controller of the personal computer, the personal computer automatically adjusts e.g., the luminosity of the LCD based on this panel ID.

As shown in FIG. 1, the panel ID is input to the video controller by a flexible printed wiring board interconnecting the LCD and the video controller. The video controller recognizes the panel ID based on the combinations of the opened and shorted states of a pre-set wiring of the flexible printed wiring board, with the opened and shorted states being 1 and 0, respectively.

However, it is necessary to prepare a flexible printed wiring board, from one type of the LCD to another, even with the same casing or the same motherboard, with the result that it takes prolonged time until the desired LCD is loaded on the personal computer, or the preparation of a new flexible printed wiring board tends to be costly.

### DISCLOSURE OF THE INVENTION

It is therefore an object of the present invention to provide for prompt and inexpensive loading of a large number of types of the LCDs.

In one aspect, the present invention provides a flexible substrate including a connector connected to a plurality of wirings and having a plurality of electrically conducting terminals and a shorting wiring interconnected for connecting to one of the plural electrically conducting terminals in the connector and for shorting to the other electrically conducting terminals.

In another aspect, the present invention provides a information processing apparatus including display means for making desired demonstration and a display control circuit for controlling the display means, in which the apparatus includes a flexible substrate including a connector connected to a plurality of wirings and having a plurality of electrically conducting terminals, a shorting wiring interconnected for connecting to one of the plural electrically conducting terminals in the connector and for shorting to the other electrically conducting terminals and discriminating means for discriminating the sorts of the display means on detecting the electrically conducting state of the shorting wiring, with the display control circuit performing display control depending on the sort discriminated by the discriminating means.

In the flexible printed wiring board and in the information processing apparatus, according to the present invention, a large number of LCDs can be loaded promptly and inexpensively.

### BRIEF DESCRIPTION OF THE DRAWINGS

FIG. 1 is an exploded perspective view of a conventional flexible printed wiring board for interconnecting an LCD and a video controller.

FIG. 2 is a perspective view showing the appearance of an embodiment of a personal computer 1 according to the present invention.

FIG. 3 is a plan view of a main body portion 2 of a personal computer 1.

FIG. 4 is an enlarged view of a jog dial 4.

FIG. 5 is a side view thereof.

FIG. 6 is an exploded perspective view of a flexible printed wiring board 11.

FIG. 7 illustrates a flexible printed wiring board 11.

FIG. 8 illustrates the structure of a single-sided flexible printed wiring board 11.

FIG. 9 illustrates the structure of a double-sided flexible printed wiring board 11.

FIG. 10 illustrates details of a panel ID setting unit 11A for the flexible printed wiring board 11.

FIG. 11 similarly illustrates details of a panel ID setting unit 11A for the flexible printed wiring board 11.

FIG. 12 similarly illustrates details of a panel ID setting unit 11A for the flexible printed wiring board 11.

FIG. 13 similarly illustrates details of a panel ID setting unit 11A for the flexible printed wiring board 11.

FIG. 14 illustrates a structure of an embodiment of a personal computer 1 according to the present invention.

FIG. 15 is a block diagram for illustrating the connection between a video controller 57 and the LCD 7.

FIG. 16 shows a typical table in which the correlation of the panel ID with the LCD type.

FIG. 17 is a schematic perspective view showing an appearance of a digital portable telephone set fitted with a camera 301.

FIG. 18 is a schematic perspective view showing a display unit 302 on rotating the camera unit.

FIG. 19 is a block circuit diagram showing the circuit structure of the digital portable telephone set fitted with a camera 301.

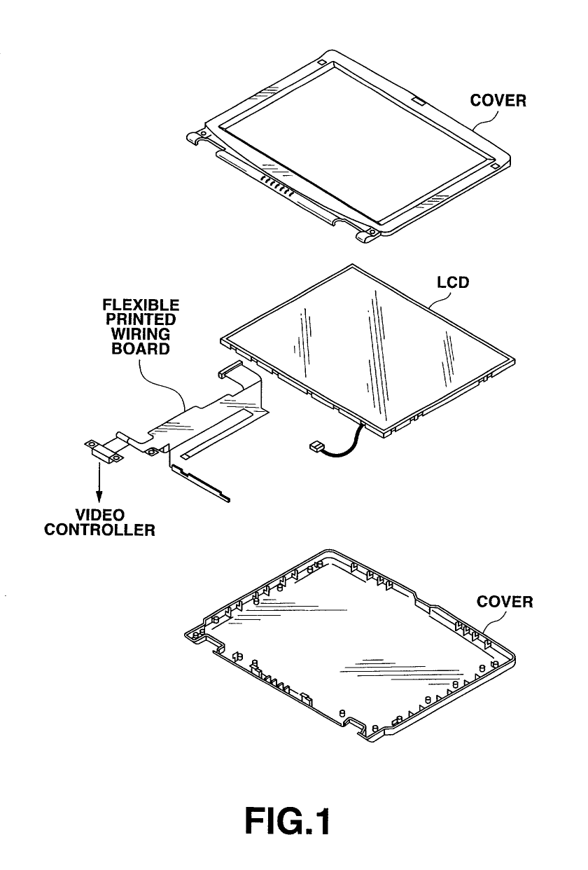

### BEST MODE FOR CARRYING OUT THE INVENTION

Referring to the drawings, preferred embodiments of according to the present invention will be explained in detail.

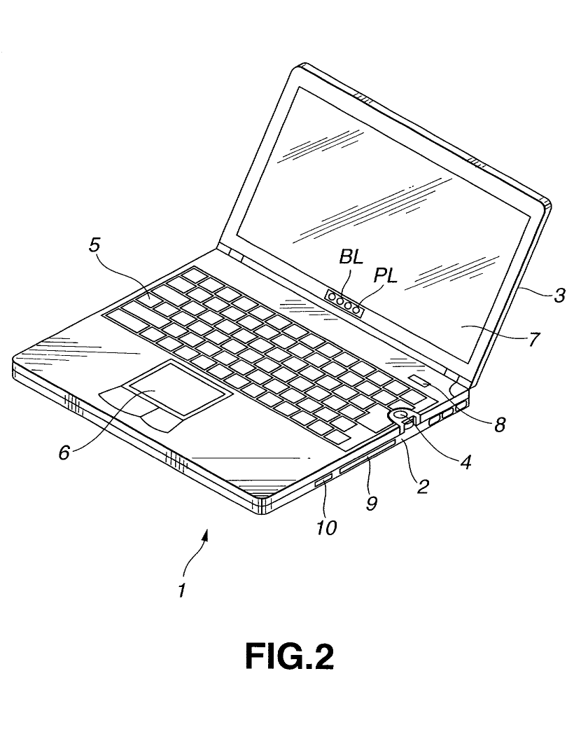

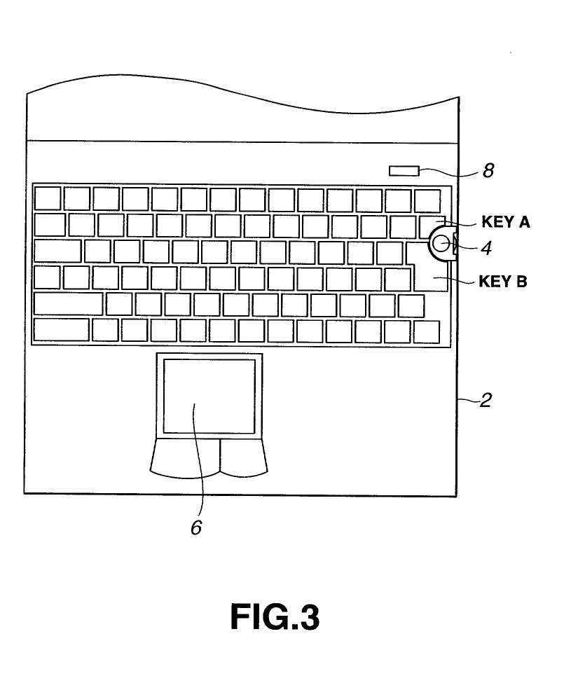

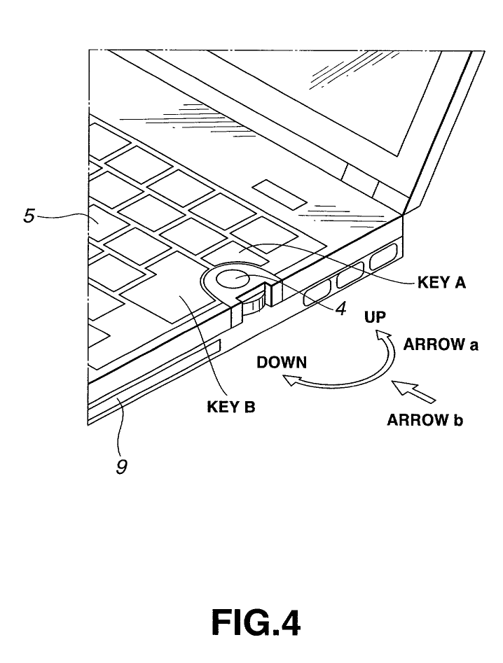

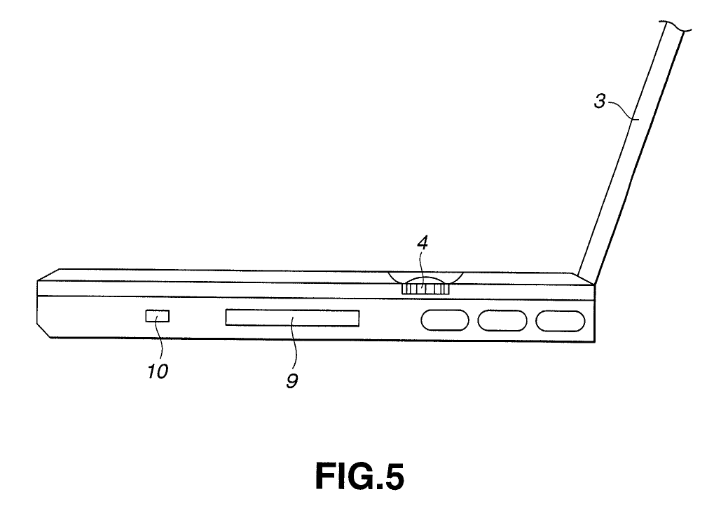

FIGS.2 to 5 illustrate the appearance of a notebook personal computer embodying the present invention. Basically, the personal computer 1 is made up of a main body portion 2 and a display unit 3 that may be opened/closed relative to the main body portion 2. FIG. 2 shows the display unit 3 in the opened state relative to the display unit 3. FIGS. 3 and 4 are a plan view of the main body portion 2 and an enlarged view of a jog dial 4 provided on the main body portion 2, respectively. FIG. 5 is a side view of the jog dial 4 provided on the main body portion 2.

On the upper surface of the main body portion 2, there are provided a keyboard 5, acted upon in inputting a variety of letters or symbols, a touch pad 6, as a pointing device, acted upon in causing the movement of a pointer (mouse cursor) displayed on an LCD 7, and a power source switch 8. On a lateral surface of the main body portion 2, there are provided the jog dial 4 and an IEEE (Institute of Electrical and Electronic Engineers) 1394 port 10. Meanwhile, a stick type pointing device may be provided instead of the touch pad 6.

On the front surface of the display unit 3, there is provided the LCD 7 for displaying an image. On the lower mid portion of the display unit 3, there are provided optional LED lamps, such as a battery lamp PL or a message lamp ML, not shown.

Meanwhile, the power source lamp PL, battery lamp BL or the message lamp ML may also be provided on an upper portion of the display unit 3.

The jog dial 4 is provided e.g., between keys A and B, arranged on the right side of the keyboard 5 on the main body portion 2 in FIG. 3, so that its upper surface is substantially flush with the keys A and B. The jog dial 4 executes pre-set processing, such as scrolling or finalizing the icon selection, responsive to rotational movement or to linear movement, respectively, indicated by arrows a and b in FIG. 4, respectively.

It is noted that the jog dial 4 may be provided on the left-hand side lateral surface of the main body portion 2, on the left-hand side or right-hand side lateral surface of the display unit 3, carrying the LCD 7, or between the keys G and H of the keyboard 5. In the latter case, the jog dial 4 is arranged in the longitudinal direction, that is so that the jog dial 4 will be rotated in the direction of the keys Y or B.

Alternatively, the jog dial 4 may be provided centrally on the forint surface of the main body portion 2 so that the jog dial 4 can be acted on with the thumb finger as the touch pad 6 is acted on with the index finger. The jog dial 4 may also be provided for extending transversely along the upper or lower edge of the touch pad 6 or longitudinally between the right and left buttons of the touch pad 6. Still alternatively, the jog dial 4 may be arranged obliquely at a pre-set angle, such as to facilitate its operation by each finger without being arranged in the longitudinal or transverse direction. The jog dial 4 may also be arranged on a lateral surface of a mouse, as a pointing device, such as to facilitate its operation with the thumb finger. As this jog dial 4, a rotary electronic component fitted with a push switch, disclosed in the Japanese Laying-Open Publication H-8-203387 filed in the name of a co-assignee as the present Assignee.

In a slot 9 is loaded a PC card for enhancing the functions of the personal computer 1, prepared on the basis of the PC Card Standard provided by the PCMCIA (Personal Computer Memory Card International Association) and by the Japan Society for Electronic Industry Promotion (body corporate). To the IEEE 1394 port 10, constructed in accordance with the standard provided in the IEEE 1394, there is connected a cable constructed in accordance with the standard provided in the IEEE 1394.

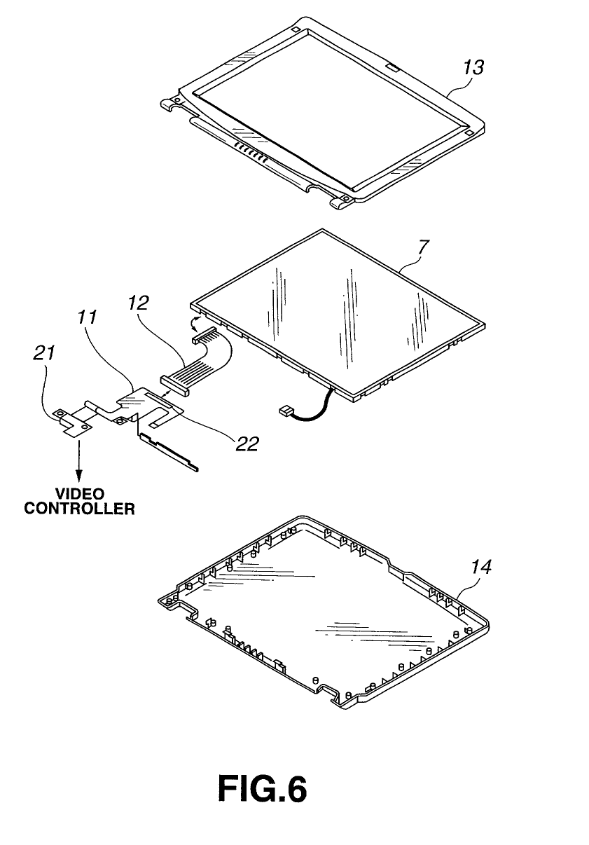

In FIG. 6, showing the manner of connection of the LCD 7 and the video controller, the flexible printed wiring board 11 for interconnecting the LCD 7 and the video controller, is connected over a connector 2 to the video controller. The flexible printed wiring board 11 is connected, over a cable 12, loaded on a connector 22, to the LCD 7 secured by covers 13, 14 for making up the display unit 3. The cable 12 is made up of plural twisted pair cables or flat cables on both ends of which are fitted connectors of pre-set shape.

With the flexible printed wiring board 11, the LCD 7 can be connected to the video controller, subject to changing the length of the cable 12 or the connector, even if, in different types of the LCDs 7, the connector positions or shape differ from one LCD to another, without the necessity of changing the structure (design) of the printed wiring board 1.

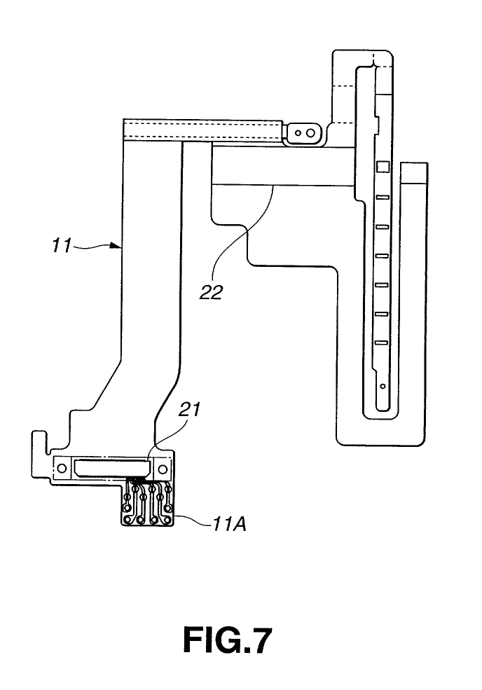

FIG. 7 shows the flexible printed wiring board 11 which is provided not only with the connector 21 and the connector 22 but also with the panel ID setting unit 11A.

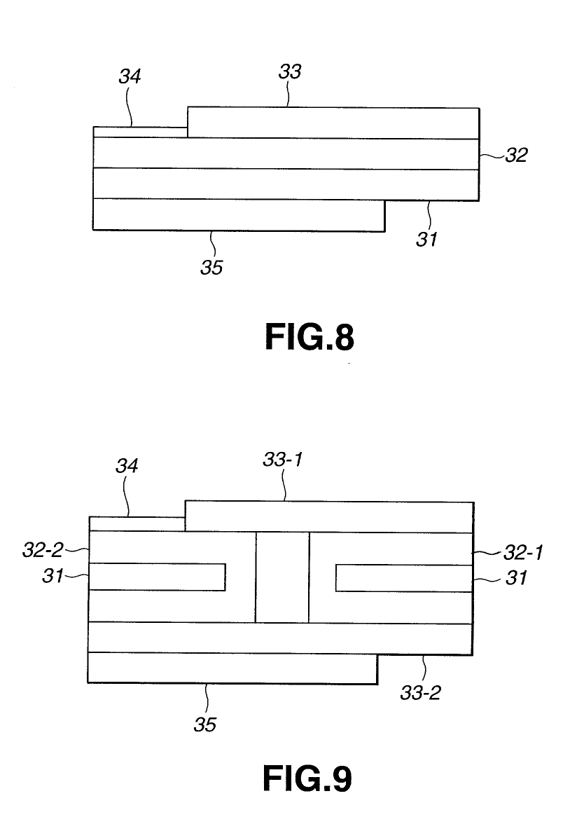

Referring to FIGS. 8 and 9, the structure of the flexible printed wiring board 11 is explained. FIGS. 8 and 9 show the structure of a single-sided flexible printed wiring board 11 and a double-sided flexible printed wiring board 11, respectively.

Referring to FIG. 8, a base film 31, as an insulating component part of the flexible printed wiring board 11, can be bent in the direction of the front side or the back side of the flexible printed wiring board 11, and has a pre-set strength. The base film 31 is e.g., a polyimide film or a polyester film. On the surface of the base film 31, there is provided a copper foil 32 on which to form lands or wiring used for furnishing electrical signals or power to components loaded on the flexible printed wiring board 11.

The portion of the flexible printed wiring board 11 that needs to be insulated from components other than the flexible printed wiring board 11 is provided with a cover film 33 constituted by a polyimide film or a polyester film, as insulating films, as an upper layer with respect to the copper foil 32. The portion of the flexible printed wiring board 11 that needs to be electrically connected to a component(s) loaded on the flexible printed wiring board 11 is provided with a surface-processed layer 34 on the copper foil 32, as obtained by soldering, such as cream soldering, or plating, such as nickel plating or gold plating.

A reinforcement 35 is formed by a polyimide film, a polyester film, a paper/phenol laminated sheet or a glass-epoxy laminated sheet, and is secured to the base film 31 for improving the strength of the flexible printed wiring board 11 in its entirety.

The front or reverse surface of the base film 31 of the double-sided flexible printed wiring board 11 is provided with a copper foil 32-1 and a copper foil 32-2, as shown in FIG. 9. It is noted that the copper films 32-1 and 32-2 are provided for being electrically connected or not electrically connected to each other. In the case of the double-sided flexible printed wiring board 11, cover films 33-1 and 33-2 are provided on the upper and lower surfaces.

In the double-sided flexible printed wiring board 11, the surface-processed layer 34 may be provided as necessary on each of the front and reverse surfaces of the flexible printed wiring board 11, in a manner not shown.

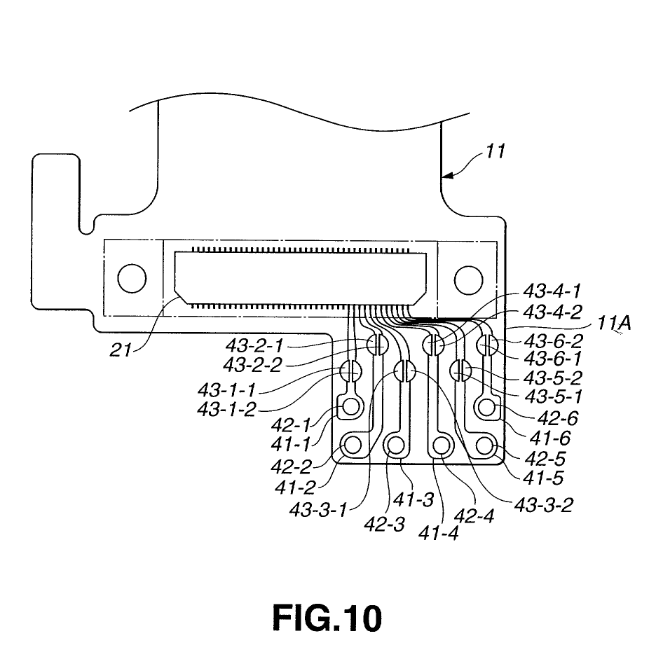

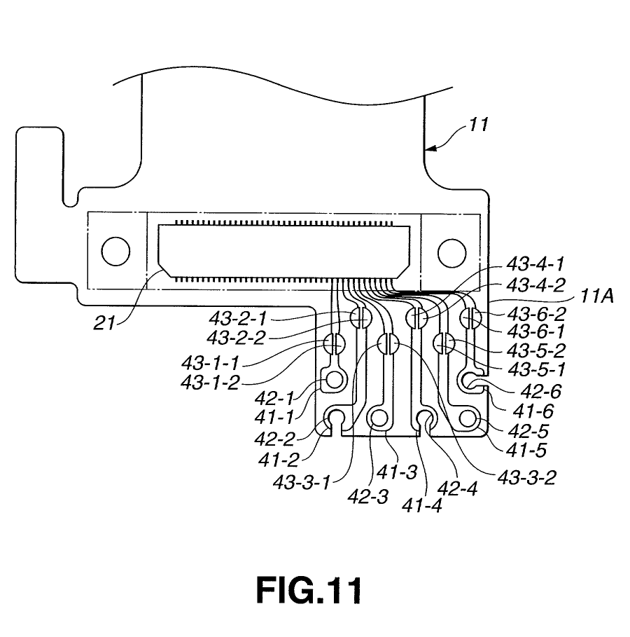

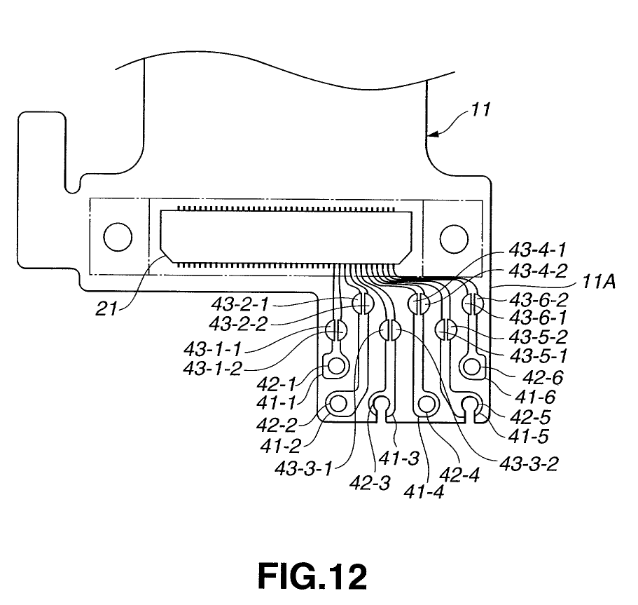

FIG. 10 shows details of the panel ID setting unit 11A of the flexible printed wiring board 11.

A wiring 41-1 is derived from a contact of the connector 21, connected to the video controller, and is connected to a land 43-1-1. The wiring 41-1, connected to the land 43-1-1, is derived from the land 43-3-1 and passed around the rim of a hole 42-1 so as to be connected to a land 43-1-2. The wiring 41-1, connected to the land 43-1-2, is connected to another contact of the connector 21 connected in turn to the video controller.

In a state shown in FIG. 10, in which one terminal and another terminal of the connector 21 are connected (shorted) to each other by the wiring 41-1, the video controller recognizes the bit of the panel ID, associated with the one and the other terminals of the connector 21, as being 0.

The hole 42-1 pierces the flexible printed wiring board 11 from the front side to the back side thereof. The front side of the land 43-1-1 in FIG. 10 is electrically connected to the wiring 41-1. The lands 43-1-1 and 43-1-2 are adapted for being insulated from each other when the wiring 41-1 is broken around the hole 42-1.

A wiring 41-2 is derived from one contact of the connector 21 connected to a video controller 57, different from the contact connecting to the wiring 41-1, and is connected to a land 43-2-1. The wiring 41-2, connected to the land 43-2-1, is derived from the land 43-2-1 and passed around the rim of a hole 42-2 so as to be connected to a land 43-2-2. The wiring 41-2, connected to the land 43-2-2, is connected to another contact of the connector 21 connected in turn to the video controller and which is not the same as the contact connecting toe the wiring 41-1.

In a state shown in FIG. 10, in which one terminal and the other terminal of the connector 21, different from the contacts connecting to the wiring 41-1, are connected (shorted) to each other by the wiring 41-2, the video controller recognizes the bit of the panel ID, associated with the one and the other terminals of the connector 21, connecting to the wiring 41-2, as being 0.

A hole 42-2 pierces the flexible printed wiring board 11 from the front side to the back side thereof. The front side of the land 43-2-1 in FIG. 10 is electrically connected to the wiring41-2. The front side of the land 43-2-1 in FIG. 10 is electrically connected to the wiring 41-2. The front side of the land 43-2-2 in FIG. 10 is electrically connected to the wiring 41-2. The lands 43-2-1 and 43-2-2 are adapted for being insulated from each other when the wiring 41-2 is broken around the hole 42-2.

A wiring 41-3 is derived from one contact of the connector 21 connected to the video controller, different from the contact connecting to the wiring 41-1 or 41-2, and is connected to a land 43-3-1. The wiring 41-3, connected to the land 43-3-1, is derived from the land 43-3-1 and passed around the rim of a hole 42-3 so as to be connected to a land 43-3-2. The wiring 41-3, connected to the land 43-3-2, is connected to another contact of the connector 21 connected in turn to the video controller. This other contact differs from the contact connecting tie wiring 41-1 or 41-2.

In a state shown in FIG. 10, in which one terminal and the other terminal of the connector 21, different from the contacts connecting to the wiring 41-1 or 41-2, are connected (shorted) to each other by the wiring 41-3, the video controller recognizes the bit of the panel ID, associated with the one and the other terminals of the connector 21, connecting to the wiring 41-3, as being 0.

A hole 42-3 pierces the flexible printed wiring board 11 from the front side to the back side thereof. The front side of the land 43-3-1 in FIG. 10 is electrically connected to the wiring 41-3. The front side of the land 43-3-2 in FIG. 10 is electrically connected to the wiring 41-3. The front side of the land 43-3-2 in FIG. 10 is electrically connected to the wiring 41-3. The lands 43-3-1 and 43-3-2 are adapted for being insulated from each other when the wiring 41-3 is broken around the hole 42-3.

A wiring 41-4 is derived from one contact of the connector 21 connected to the video controller, different from the contact connecting to the wirings 41-1 to 41-3, and is connected to a land 43-4-1. The wiring 41-4, connected to the land 43-4-1, is derived from the land 43-4-3 and passed around the rim of a hole 42-4 so as to be connected to a land 43-4-2. The wiring 41-4, connected to the land 43-4-2, is connected to another contact of the connector 21 connected in turn to the video controller. This other contact is not the same as the contacts connecting to the wirings 41-1 to 41-3.

In a state shown in FIG. 10, in which one terminal and the other terminal of the connector 21, both different from the contacts connecting to the wiring 41-1 or 41-2, are connected (shorted) to each other by the wiring 41-4, the video controller recognizes the bit of the panel ID, associated with the one and the other terminals of the connector 21, connecting to the wiring 41-4, as being 0.

The hole 42-4 pierces the flexible printed wiring board 11 from the front side to the back side thereof. The front side of the land 43-4-1 in FIG. 10 is electrically connected to the wiring 41-4. The front side of the land 43-4-2 in FIG. 10 is electrically connected to the wiring 41-4. The lands 434-1 and 43-4-2 are adapted for being insulated from each other when the wiring 41-4 is broken around the hole 42-3.

A wiring 41-5 is derived from one contact of the connector 21 connected to the video controller, different from the contact connecting to the wirings 41-1 to 41-4, and is connected to a land 43-5-1. The wiring 41-5, connected to the land 43-5-1, is derived from the land 43-5-1 and passed around the rim of a hole 42-5 so as to be connected to a land 43-5-2. The wiring 41-5, connected to the land 43-5-2, is connected to another contact of the connector 21 connected in turn to the video controller. This other contact is not the same as the contacts connecting to the wirings 41-1 to 414.

In a state shown in FIG. 10, in which one terminal and the other terminal of the connector 21, both different from the contacts connecting to the wiring 41-1 or 41-2, are connected (shorted) to each other by the wiring 41-5, the video controller recognizes the bit of the panel ID, associated with the one and the other terminals of the connector 21, connecting to the wiring 41-5, as being 0.

The hole 42-5 pierces the flexible printed wiring board 11 from the front side to the back side thereof. The front side of the land 43-5-1 in FIG. 10 is electrically connected to the wiring 41-5. The front side of the land 43-5-2 in FIG. 10 is electrically connected to the wiring 41-5. The front side of the land 43-5-2 in FIG. 10 is electrically connected to the wiring 41-5. The lands 43-5-1 and 43-5-2 are adapted for being insulated from each other when the wiring 41-5 is broken around the hole 42-3.

A wiring 41-6 is derived from one contact of the connector 21 connected to the video controller, different from the contacts connecting to the wirings 41-1 to 41-5, and is connected to a land 43-6-1. The wiring 41-6, connected to the land 43-6-1, is derived from the land 43-6-1 and passed around the rim of a hole 42-6 so as to be connected to a land 43-6-2. The wiring 41-6, connected to the land 43-6-2, is connected to another contact of the connector 21 connected in turn to the video controller. This other contact is not the same as the contacts connecting to the wirings 41-1 to 41-5.

In a state shown in FIG. 10, in which one terminal and the other terminal of the connector 21, different from the contacts connecting to the wirings 41-1 to 41-5, are connected (shorted) to each other by the wiring 41-6, the video controller recognizes the bit of the panel ID, associated with the one and the other terminals of the connector 21, connecting to the wiring 41-6, as being 0.

The hole 42-6 pierces the flexible printed wiring board 11 from the front side to the back side thereof. The front side of the land 43-6-1 in FIG. 10 is electrically connected to the wiring 41-6. The front side of the land 43-6-2 in FIG. 10 is electrically connected to the wiring 41-6. The front side of the land 43-6-2 in FIG. 10 is electrically connected to the wiring 41-6. The lands 43-6-1 and 43-6-2 are adapted for being insulated from each other when the wiring 41-6 is ruptured around the hole 42-3.

Thus, in the state shown in FIG. 10, the video controller recognizes the panel ID as being 000000.

Although the panel ID which the flexible printed wiring board 11 permits the video controller to recognize is of 6 bits, in the case of FIG. 10, it may be of any suitable number of bits, depending on, for example, the sort of the LCD.

The panel ID setting unit 11A of the flexible printed wiring board 11 for permitting the video controller to recognize the panel ID of the pre-set bit pattern is hereinafter explained.

For example, if the panel ID is to be set to 101010, the wiring 41-6 is broken around the hole 42-6 by a pre-set tool or jig. Similarly, the wiring 41-4 is broken around the hole 42-4, whilst the wiring 41-2 is broken around the hole 42-2.

If the wiring 41-6 is ruptured, the one and the other contacts of the connector 21, connecting to the wiring 41-6, are insulated, so that the video controller recognizes the uppermost bit of the panel ID as being 1. Similarly, if the wiring 41-4 is ruptured, the one and the other contacts of the connector 21, connecting to the wiring 41-4, are insulated, so that the video controller recognizes the third upper bit of the panel ID as being 1, whereas, if the wiring 41-2 is ruptured, the one and the other contacts of the connector 21, connecting to the wiring 41-2, are insulated, so that the video controller recognizes the fifth upper bit of the panel ID as being 1.

So, the video controller recognizes the panel ID as being 101010.

For example, if the panel ID is to be set to 010100, the wiring 41-5 is broken around the hole 42-5 by a pre-set tool or jig. Similarly, the wiring 41-3 is is broken around the hole 42-3.

If the wiring 41-5 is ruptured, the one and the other contacts of the connector 21, connecting to the wiring 41-5, are insulated, so that the video controller recognizes the second upper bit of the panel ID as being 1. Similarly, if the wiring 41-3 is ruptured, the one and the other contacts of the connector 21, connecting to the wiring 41-3, are insulated, so that the video controller recognizes the fourth upper bit of the panel ID as being 1.

So, the video controller recognizes the panel ID as being 101010.

Meanwhile, the wirings 41-1 to 41-6 may be associated with bits of the panel ID in any optional manner without limitation to the array of the wirings on the panel ID setting unit 11A.

When severing the wirings 41-1 to 41-6 using e.g., an automatic machine or a jig, the automatic machine or the jig for cutting the flexible printed wiring board 11 as well as the wirings 41-1 to 41-6 severs the flexible printed wiring board 11 so that the cutting edge of the tool loaded affects one or more of the holes 42-1 to 42-6. By so doing, the portion of the flexible printed wiring board 11 to be severed along with the wirings 41-1 to 41-6 can be positively removed, without remnant connecting portions to the flexible printed wiring board 11, even if the cutting edge of the tool has become dull.

Moreover, the holes 42-1 to 42-6 prevent the cracking of the flexible printed wiring board 11 likely to be produced in severing the wirings 41-1 to 41-6.

If a cutting tool, such as a nipper or a cutter, is used to sever one or more of the wirings 41-1 to 41-6, the wirings 41-1 to 41-6 can be severed by cutting twice so that the cutting edge affects the holes 42-1 to 42-6.

The processing for rendering the erroneously cut wirings 41-1 to 41-6 electrically conductive is explained.

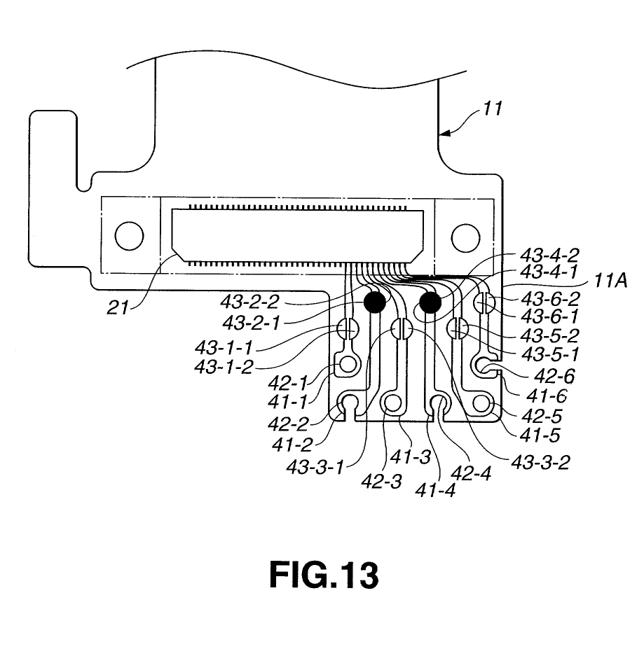

If the panel ID is set to 100000, but the wirings 41-2 and 41-4 are cut, the lands 43-2-1 and 43-2-2 are soldered and rendered electrically conductive, while the lands 43-4-1 and 43-4-2 are soldered and rendered electrically conductive, as shown in FIG. 13.

Since the wiring 41-2 is electrically connected, the video controller recognizes the fifth upper bit of the panel ID as being 0. On the other hand, since the wiring 41-4 is electrically connected, the video controller recognizes the third upper bit of the panel ID as being 0.

If one of the wirings 41-2 and 41-4 is cut, the wirings 41-1 to 41-6 can be rendered electrically conductive extremely readily by rendering paired lands 43-3-1 to 43-6-2 electrically conductive.

The method for rendering the paired lands 43-3-1 to 43-6-2 electrically conductive may, for example, be by bonding, without being limited to soldering.

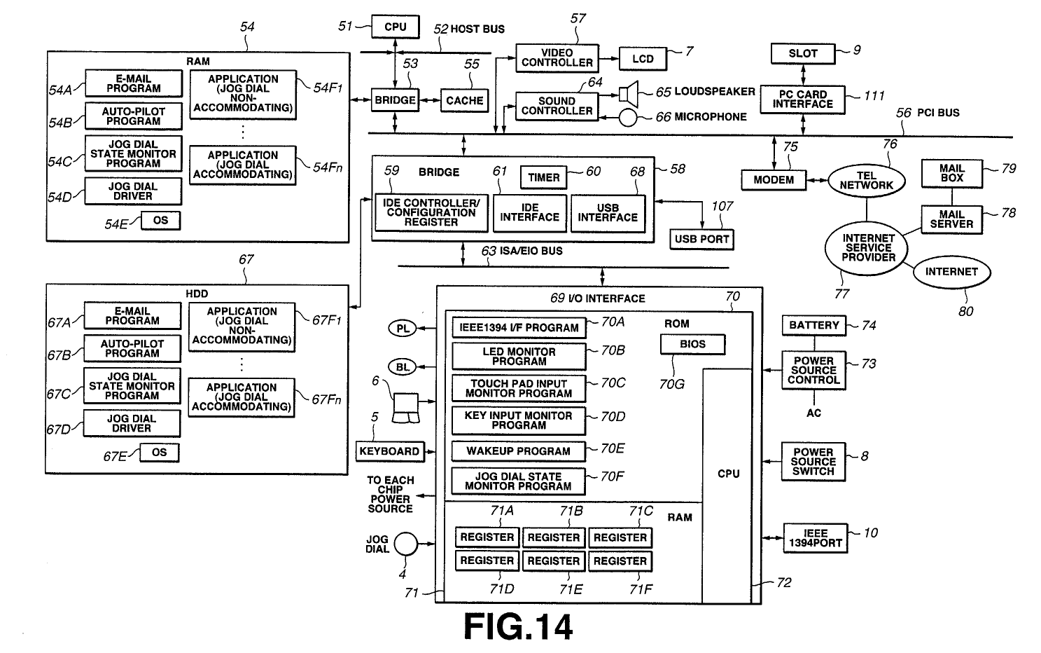

Referring to FIG. 14, an embodiment of the personal computer 1 according to the present invention is hereinafter explained.

The central processing unit (CPU) 51 may, for example, be a Pentium (trademark) processor manufactured by Intel Inc., and is connected to a host bus 52. To the host bus 52 is further connected a bridge 53 (so-called north bridge) which in turn is connected to a PCI (peripheral component interconnect/interface) bus 56.

The bridge 53 is comprised e.g., of AGP host bridge controller 400 BX, manufactured by Intel Inc., and controls the CPU 51 and the RAM (random access memory) 54 (so-called main memory). Moreover, the bridge 53 controls the video controller 57 over the PCI bus 56. Meanwhile, the bridge 53 and another bridge 58 (so-called south bridge (PCI-ISA bridge)) make up a so-called chip set.

The bridge 53 is also connected to a cache memory 55. This cache memory is comprised of a memory executing write or readout processing at a higher speed than the RAM 54, such as SRAM (static RAM), and caches (transiently stores) the program or data used by the CPU 51.

Meanwhile, the CPU 51 includes an internal primary cache memory, which operates at a higher speed than the cache memory 55 and which is controlled by the CPU 51 itself.

The RAM 54 is formed e.g., by a DRAM (dynamic RAM) for storage of the program executed by the CPU 51 or data required for the operation of the CPU 51. Specifically, the RAM 54 stores an electronic mail program 54A, an auto-pilot program 54B, a jog dial status monitoring program 54C, a jog dial driver 54D, an operating program (OS) 54E and other application programs 54F1 to 54 Fn, loaded from an HDD 67, at a time point of completion of booting.

The electronic mail program 54A transmits/receives a message (so-called Email) over a communication network, such as a telephone network 76. The electronic mail program 54A has an incoming mail acquisition function. This incoming mail acquisition function inquires a mail server 78, provided in the Internet service provider 77, as to whether or not there is any incoming mail addressed to a user in a mail box 79. If there is any mail addressed to the user, the incoming mail acquisition function executes the processing of acquiring the mail.

The auto-pilot program 54B sequentially boots plural pre-set processing operations or a pre-set program in accordance with a pre-set sequence to execute the processing operations.

The jog dial status monitoring program 54C receives from each application program a notification as to whether or not the jog dial 4 is being coped with and, if the jog dial status is coped with, makes display on the LCD 7 what can be done on actuating the jog dial 4.

The jog dial status monitoring program 54C detects an event of the jog dial 4, that is rotation of the jog dial 4 in the direction indicated by arrow a in FIG. 4 or thrusting in the direction indicated by arrow b in FIG. 4, by way of an example, to execute the processing corresponding to the detected event. The jog dial status monitoring program 54C includes a list for receiving the notification from the application program. The jog dial driver 54D is responsive to the operation on the jog dial 4 to execute a variety of functions.

The operating system (OS) 54E is a program controlling the basic operations of a computer, such as, for example, the Windows 95 (trademark) or Windows 98 (trademark) manufactured by Microsoft Inc., or MAC OS (trademark) manufactured by the Apple Computer Inc.

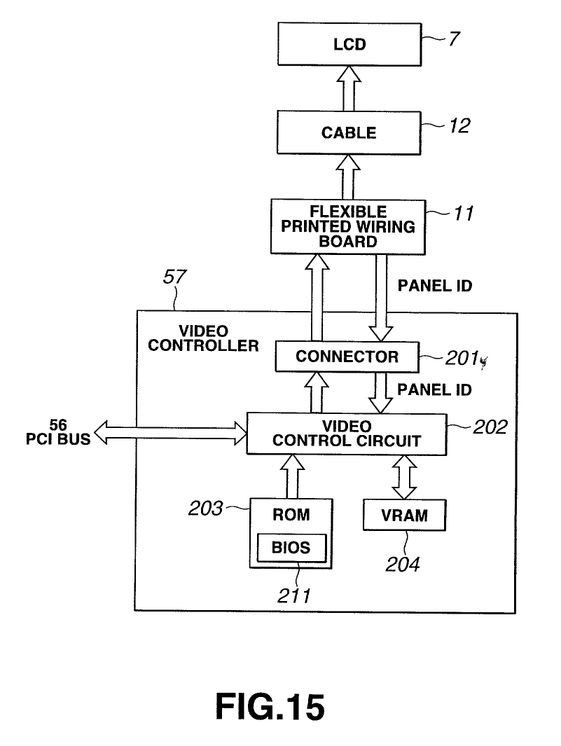

The video controller 57 is connected over the PCI bus 56 to the bridge 53 to receive data supplied from the CPU51 over the PCI bus 56 and the bridge 53, such as image data or text data, to generate image data corresponding to the received data or to store the received data directly in an enclosed VRAM (video RAM) 204, which will be explained subsequently in detail by referring to FIG. 15. The video controller 57 furnishes the image data to the LCD 7 of the display unit 3 through the flexible printed wiring board 11 and the cable 12 to display an image corresponding to the image data stored in the VRAM 204.

To the PCI bus 56 is connected a sound controller 64 which captures signals corresponding to the speech from a microphone 66 to generate data corresponding to the speech which then is output to the RAM 54. Alternatively, the sound controller 64 drives the loudspeaker 65 to output the speech.

To the PCI bus 56 is also connected a MODEM 75 which transmits pre-set data to a communication network 80, such as Internet, or to a mail server 78, over the public telephone network 76 and the Internet service provider 77, while receiving preset data from the communication network 80 or the mail server 78.

A PC card interface 111, connected to the PCI bus 56, furnishes data supplied from a PC card, not shown, loaded in the slot 9, to the CPU 51 or RAM 54, while outputting the data furnished from the CPU 51 to the PC card.

To the PCI bus 56 is also connected the bridge 58 (so-called south bridge) which, constituted by e.g., PIIX4 E manufactured by Intel Inc., has enclosed therein an IDE (Integrated Drive Electronics) controller/configuration register 59, a timer circuit 60, an IDE interface 61 and a USB interface 68. The bridge 58 controls a variety of I/O (input/output) operations, such as by controlling devices connected to the IDE bus 62 or devices connected over the ISA/EIO (Industry Standard Architecture/Extended Input Output) bus 63 or an I/O interface 69.

An IDE controller/configuration register 59 is made up of two IDE controllers, namely a so-called primary IDE controller and a secondary IDE controller, not shown, and a configuration register, also not shown.

To the primary IDE controller is connected an HDD 67 over the IDE bus 62. To the secondary IDE controller is electrically connected an IDE device, such as a CDROM drive or HDD, when such IDE device is loaded on another IDE bus.

Meanwhile, the HDD 67 records the electronic mail program 67A, auto-pilot program 67B, jog dial status monitoring program 67C, jog dial driver 67D, OS 67E and other plural application programs 67F1 to 67Fn. These programs (electronic mail program 67A, auto-pilot program 67B, jog dial status monitoring program 67C, jog dial driver 67D, OS 67E and other plural application programs 67F1 to 67Fn) are sequentially furnished to the RAM 54 in the course of the booting processing for loading thereon.

The USB interface 68 receives data from a device, connected in circuit, over a USB port 107, to transmit the received data over the PCI bus 56 to the CPU 51 or to the RAM 54. The USB interface 68 transmits the data furnished from the CPU 51 or from the RAM 54 to the device connected in circuit over the USB port 107.

A timer circuit 60 is responsive to requests from the OS 54E to furnish data indicating the current time over the PCI bus 56 to the CPU 51 or to the RAM 54.

To the ISA/EIO bus 63 is further connected the I/O interface 69 which is comprised of an embedded controller and in which there are interconnected a ROM 70, a RAM 71 and a CPU 72.

The ROM 70 has stored therein an IEEE interface program 70A, an LED control program 70B, a touch-pad input monitoring program 70C, a key input monitoring program 70D, a wakeup program 70E and a jog dial status monitoring program 70F.

The IEEE interface program 70A transmits/receives data conforming to a standard provided in IEEE 1394 over the IEEE 1394 port 10 (data stored in a packet). The LED control program 70B controls the lighting of the power source lamp PL, battery source lamp BL, message lamp ML, as necessary, and other LED lamps. The touch-pad input monitoring program 70C monitors an input from the touch pad 6 responsive to the user actuation.

The key input monitoring program 70D monitors an input from the keyboard or other key switches. The wakeup program 70E checks whether or not the current time is the pre-set time, based on the current time data furnished from the timer circuit 60 of the bridge 58, to boot a pre-set processing or program at the pre-set time, by way of supervising the power source of each chip of the personal computer 1. The jog dial status monitoring program 70F perpetually monitors whether or not the rotary encoder of the jog dial 4 has been rotated or thrust.

The ROM 70 also has stored therein a BIOS (Basic Input/Output System) 70G which exercises control in exchanging (inputting/outputting) data between the OS or the application program and peripherals (touch pad 6, keyboard 5 or the HDD 67).

The RAM 71 includes registers for LED control, touch pad input status, key input status or time setting, I/O registers for monitoring the jog dial status, and the IEEE1394 I/F register, as registers 71A to 71F. For example, if the jog dial 4 is pressed to boot the electronic mail program 54A, a pre-set value is stored in the LED control register to control the lighting of the message lamp ML in keeping with the stored value. When the jog dial 4 is pressed, a pre-set operating key flag is stored in the key input status register. In the setting time register, pre-set time is set in keeping with actuation of the keyboard 5 by the user.

To this I/O interface 69 are also connected the jog dial 4, touch pad 6 and the IEEE 1394 port 10, through connectors, not shown, to output signals associated with the jog dial 4, touch pad 6 or the keyboard 5 to the ISA/EIO bus 63. The I/O interface 69 also controls the transmission/reception of data with the equipment, connected in circuit, over the IEEE 1394 port 10. To the I/o interface 69 are also connected lamps, such as power source lamp PL, battery source lamp BL, message lamp ML, power source control circuit 73 and other LED lamps.

The power source control circuit 73 is connected to an enclosed battery 74 or to an AC power source and furnishes the necessary power to each block while exercising control to charge the enclosed battery 74 or the second battery of a peripheral device. The I/O interface 69 monitors the power source switch 8 which is acted on in turning the power source on or off.

The I/O interface 69 executes the various programs from the IEEE interface program 70A up to the jog dial status monitoring program 70F, even if the power source is turned off, by an internal power source. That is, the programs from the IEEE interface program 70A up to the jog dial status monitoring program 70F are running at all times.

Thus, even if the power source switch 8 is turned off, such that the CPU 51 is not executing the OS 54E, the I/O interface 69 executes the jog dial status monitoring program 70F, so that, if, in the power save mode or in the power source off state, the jog dial 4 is pressed, the personal computer 1 boots the processing of a pre-set software or script file.

Thus, in the personal computer 1, there is no necessity for providing a dedicated key, because the jog dial 4 has the programmable power key function.

The panel ID based processing of the video controller 57 is hereinafter explained. FIG. 15 is a block diagram for illustrating the connection between the video controller 57 and the LCD 7.

A video control circuit 202 of the video controller 57 is constituted by e.g., a graphics control IC having a so-called video accelerator function, and expands data furnished from the CPU 51 or RAM 54 into image data which is then stored in a VRAM 204. The video control circuit 202 controls the operation of the LCD 7 through the flexible printed wiring board 11 and the cable 12, while furnishing image data for demonstrating a pre-set image to the LCD 7 based on the image data expanded in the VRAM 204.

When e.g., the personal computer 1 is booted, the video control circuit 202 sets the panel ID based on whether or not the wirings 41-1 to 41-6 of the flexible printed wiring board 11, connected through a connector 201 of the video controller 57 have been severed.

The video control circuit 202 has pre-stored therein a table indicating the correspondence between the panel ID and the LCD sort. The video control circuit 202 specifies the sort of the LCD 7, connected in circuit, based on the pre-stored table and the panel ID.

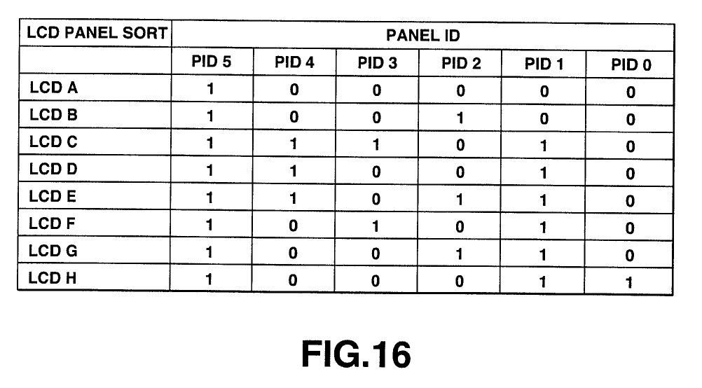

FIG. 16 shows a typical table indicating the correspondence between the panel ID and the LCD sort.

In the typical table, shown in FIG. 16, the PID 5, corresponding to the uppermost bit of the panel ID, is set to 0 when the wiring 41-6 is electrically conductive (that is when the wiring 41-6 is not ruptured or when the lands 43-6-1 and 43-6-2 are soldered together), while being set to 1 when the wiring 41-6 is electrically insulated (that is when the wiring 41-6 is ruptured or when the lands 43-6-1 and 43-6-2 are not soldered together). In the typical table, shown in FIG. 16, the PID 4, corresponding to the second upper bit of the panel ID, is set to 0 or 1 when the wiring 41-5 is electrically conductive or insulated, respectively.

In the typical table, shown in FIG. 16, the PID 3, corresponding to the third upper bit of the panel ID, is set to 0 or 1 when the wiring 41-4 is electrically conductive or insulated, respectively. In the typical table, shown in FIG. 16, the PID 2, corresponding to the fourth upper bit of the panel ID, is set to 0 or 1 when the wiring 41-3 is electrically conductive or insulated, respectively.

In the typical table, shown in FIG. 16, the PID 1, corresponding to the fifth upper bit of the panel ID, is set to 0 or 1 when the wiring 41-2 is electrically conductive or insulated, respectively. In the typical table, shown in FIG. 16, the P ID 0, corresponding to the lowermost bit of the panel ID, is set to 0 or 1 when the wiring 41-1 is electrically conductive or insulated, respectively.

For example, if the wiring 41-6 is insulated, with the wirings 41-1 to 41-5 are electrically conductive, the video control circuit 202 sets the panel ID to 100000, and recognizes, from the panel ID thus set and the table shown in FIG. 16, that the LCD 7 connected in circuit is the LCD A.

Similarly, if the wirings 41-6 and 41-3 are insulated, with the wirings 41-1, 41-2, 41-4 and 41-5 are electrically conductive, the video control circuit 202 sets the panel ID to 100100, and recognizes, from the panel ID thus set and the table shown in FIG. 16, that the LCD 7 connected in circuit is the LCD B.

Thus, the video control circuit 202 recognizes the sort of the LCD 7 connected in circuit based on the insulated or conducting state of the wirings 41-1 to 41-6 and on the table having stored therein the relation of correspondence between the panel ID and the LCD sort.

The video control circuit 202 also memorizes the setting of luminosity and resolution or the setting of the image data transmission period in association with the sort of the LCD 7.

The ROM 203 memorizes the BIOS 211, as a program for controlling data inputting/outputting of the video control circuit 202.

When executing the BIOS 211, the video control circuit 202 sets the BIOS 211, based on the panel ID and on the aforementioned table, so that the BIOS 211 will be in meeting with the sort of the LCD 7 as recognized. That is, the video control circuit 202 sets the setting of luminosity and resolution or the setting of the image data transmission period, therein stored in association with the sort of the LCD 7.

Thus, the video controller 57 is able to set luminosity and resolution or the setting of the image data transmission period, in association with the sort of the LCD 7, based on the insulating or conducting state of the wirings 41-1 to 41-6 of the panel ID setting unit 11A of the flexible printed wiring board 11 connected in circuit.

In the foregoing explanation, the table indicating the correspondence between the panel ID and the LCD sort is stored in the video control circuit 202. Alternatively, the table indicating the correspondence between the panel ID and the LCD sort may be stored in the ROM 203.

The ROM 203 may be provided within the video control circuit 202.

It is also possible with the personal computer 1 to set not only the LCD 7 but also the sound controller 64, as an example, based on an ID as set by the flexible printed wiring board 11.

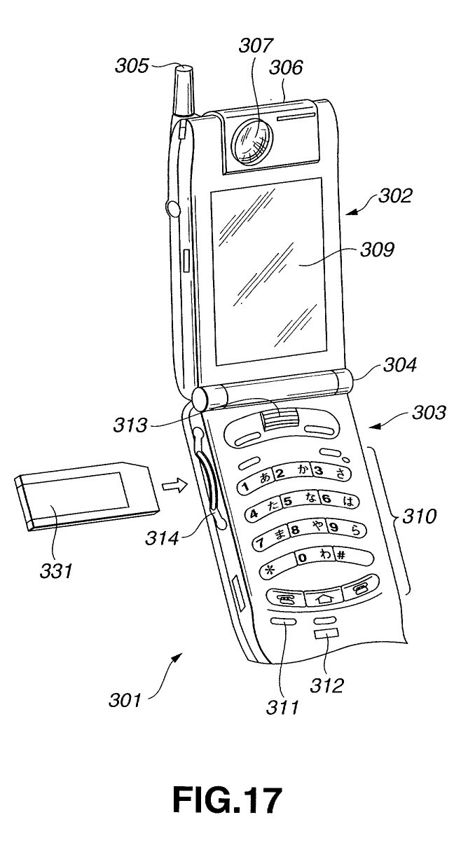

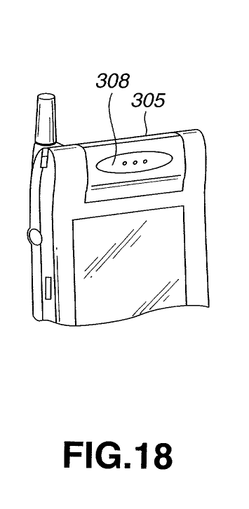

The appearance of the digital portable telephone set fitted with a camera 301, embodying the present invention, is now explained. Referring to FIG. 17, the digital portable telephone set fitted with a camera 301 includes a display unit 302 and a main body portion 303, and may be collapsed along a center hinge 304.

The display unit 302 includes, on an upper left corner, a transmission/reception antenna 305 that may be retracted or extended as desired. The digital portable telephone set fitted with a camera 301 transmits/receives electrical waves to or from a base station, as a stationary radio station, over the antenna 305.

The display unit 302 includes, at an upper mid portion, a camera unit 306 rotatable through approximately 180°. The digital portable telephone set fitted with a camera 301 images a desired object by a CCD camera 307 of the camera unit 306.

When the camera unit 306 is positioned by a user at an approximately 180° rotated position, the display unit 302 is positioned directly facing a loudspeaker 308 provided at a mid backside portion of the camera unit 306. This switches the digital portable telephone set fitted with a camera 301 to the usual speech call state.

A liquid crystal display 309 is provided directly facing the display unit 302. The liquid crystal display 309 demonstrates the contents of an E-mail, simple home page, and an image photographed by the CCD camera 307 of the camera unit 306, in addition to the state of reception of electrical waves, residual battery capacity, name of the called party registered as a telephone directory and transmission hysteresis.

The main body portion 303 is provided on its surface with number keys from 0 to 9, and operating keys 310, namely a calling key, a redial key, a call terminating and power source key, a clear key and an E-mail key. A variety of instructions, corresponding to the operation of the operating keys 310, are input to the digital portable telephone set fitted with a camera 301.

On the lower side of the operating keys 310 on the main body portion 303, there are provided a memo button 311 and a microphone 312. When the memo button 311 is acted on, the digital portable telephone set fitted with a camera 301 records the speech of the called party. The digital portable telephone set fitted with a camera 301 collects the speech of the called party during the all over the microphone 312.

On an upper portion rotatable jog dial 313 of the operating keys 310 on the main body portion 303, there is provided a rotatable jog dial 313 so as to be slightly protruded from the surface of the main body portion 303. The digital portable telephone set fitted with a camera 301 is responsive to the rotation of the jog dial 313 to execute the scrolling of the telephone directory list or the E-mails, demonstrated on the liquid crystal display 309, the page turning over operation of the simple hole page or the image feed operation.

For example, the main body portion 303 is responsive to the rotation of the jog dial 313 by the user to select the desired telephone number from the plural telephone numbers of the telephone directory demonstrated on the liquid crystal display 309. When the jog dial 313 is pressed towards the inner part of the main body portion 303, the main body portion 303 finalizes the selected telephone number to make automatic call processing for the finalized telephone number.

Meanwhile, a battery pack, not shown, is loaded on the back side of the main body portion 303. When the call termination/power source key is on, the battery pack delivers the power to each circuit section to establish the operation enabling state.

The upper left lateral surface of the main body portion 303 is provided with a memory stick slot 314 in which to load removably a memory stick (trademark owned by the present Assignee) 331. When a memo button 311 is pressed, the digital portable telephone set fitted with a camera 301 causes the speech of the called party to be recorded in the memory stick 311 loaded thereon. The digital portable telephone set fitted with a camera 301 is responsive to the user operation to record the E-mail, simple home page and an image photographed by the CCD camera 307 in the memory stick 311 loaded thereon.

The memory stick 331 is a sort of a flash memory card developed by the SONY Corporation, the present Assignee. This memory stick 331 is a flash memory device, as a sort of the EEPROM (electrically erasable and programmable read-only memory) as an electrically rewritable and rewritable non-volatile memory, enclosed in a small-sized thin type plastic casing 22.5 mm in length, 50 mm in width and 3.8 mm in thickness. It enables variable data, such a images, speech or music to be written or read out via an IO pin terminal.

Moreover, the memory stick 331 adopts a unique serial protocol which assures compatibility on an equipment in use despite changes in the specifications of the enclosed flash memory caused by the increased capacity to realize the maximum writing speed of 1.5 MB/s and the maximum readout speed of 2.45 MB/s and uses an inadvertent erasure preventative switch to assure high operational reliability.

Thus, with the digital portable telephone set fitted with a camera 301, on which can be loaded the memory stick 331, data can be co-owned with other electronic equipment through the memory stick 331.

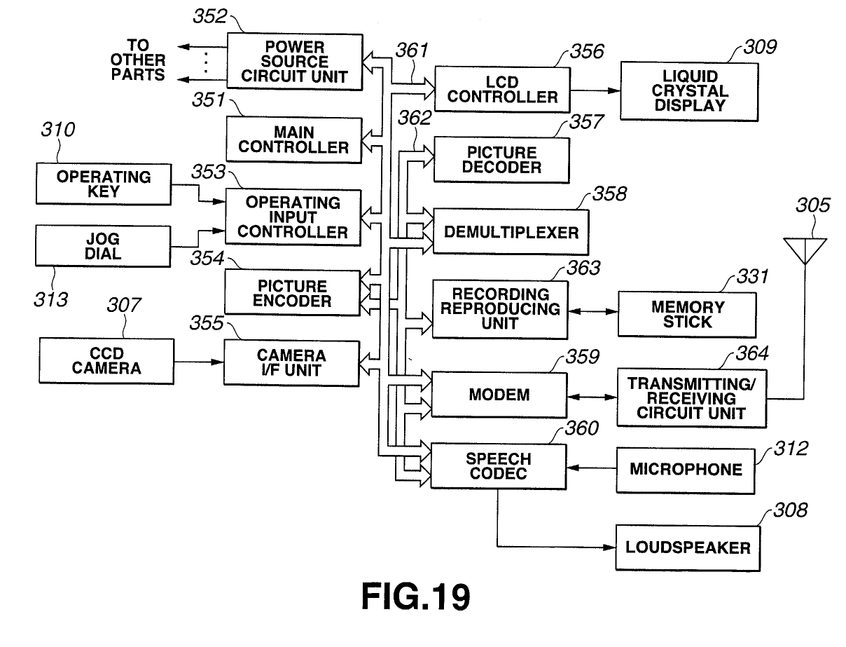

Referring to FIG. 19, showing the circuit structure of the digital portable telephone set fitted with a camera 301 in its entirety, a power source circuit 352, an operating input control unit 353, an image encoder 354, a camera interfacing unit 355, an LCD (liquid crystal display) controller 356, an image decoder 357, a demultiplexer 358, a storage reproducing unit 363, a MODEM circuit 359 and a speech codec 360 are interconnected over a main bus 361 and to a main controller 351, comprehensively controlling the display unit 302 and the main body portion 303, whilst the image encoder 354, image decoder 357, demultiplexer 358, MODEM circuit section 358 and the speech codec 360 are interconnected over a synchronization bus 362.

When the call termination/power source key is turned on by user actuation, the electric power is furnished from the battery pack to respective parts to enable the operation of the digital portable telephone set fitted with a camera 301.

In the speech call mode, the digital portable telephone set fitted with a camera 301 converts the speech signal collected by the microphone 312 into digital speech data by the speech codec 360 under control by the main controller 351 comprised of the CPU, ROM and the RAM. In the digital portable telephone set fitted with a camera 301, the digital speech data is spread-spectrum processed in the MODEM circuit section 359 and subjected in the transmission/reception circuit 364 to D/A conversion and frequency conversion so as to be then transmitted over the antenna 305.

In the speech call mode, the digital portable telephone set fitted with a camera 301 amplifies the signals received over the antenna 305. The amplified signals are frequency converted and AID converted so as to be spectrum-despread and converted by the speech codec 360 into analog speech signals. The digital portable telephone set fitted with a camera 301 outputs the speech corresponding to the analog speech signals at the loudspeaker 308.

In transmitting an E-mail in the data communication mode, the digital portable telephone set fitted with a camera 301 sends out the text data f the E-mail, input by the operation on the actuating key 310 and the jog dial 313, to the main controller 351 through the operating input control unit 353.

The main controller 351 spectrum-spreads the text data in the MODEM circuit 359 and subjects the resulting data to D/A conversion and frequency conversion in the transmission/reception circuit 364 before transmitting the data over the antenna 305 to the base station.

In receiving an E-mail in the data communication mode, the digital portable telephone set fitted with a camera 301 spectrum-dispread signals, received from a base station CS3 over the antenna 305, in the MODEM circuit 359, to restore the original data, which then is displayed as an E-mail on the liquid crystal display 309 through the LCD controller 356.

Similarly to the flexible printed wiring board 11, the LCD controller 356 is connected to the liquid crystal display 309 through the flexible printed wiring board having the panel ID setting unit.

The digital portable telephone set fitted with a camera 301 then is also able to record the received E-mail in the memory stick 311 through the storage reproducing unit 363 responsive to the user actuation.

In transmitting image data in the data communication mode, the digital portable telephone set fitted with a camera 301 furnishes the image data, photographed by the CCD camera 307, through the camera interfacing unit 355 to the image encoder 354.

If the image data is not transmitted, it is possible for the digital portable telephone set fitted with a camera 301 to display the image data, photographed in the CCD camera 307, directly on the liquid crystal display 309 through the camera interfacing unit 355 and the LCD controller 356.

The image encoder 354 converts the image data, furnished from the CCD camera 307, in accordance with a pre-set encoding system, such as MPEG (Moving Picture Experts Group) 2 or MPEG 4, by compression encoding into encoded image data, which then is transmitted to the demultiplexer 358.

At this time, the digital portable telephone set fitted with a camera 301 simultaneously sends the speech, collected by the microphone 312 by the CCD camera 307 during imaging, as digital speech data over the speech codec 360 to the demultiplexer 358.

The demultiplexer 358 multiplexes the encoded image data, furnished from the image encoder 354, and the speech data, furnished from the speech codec 360, in accordance with a pre-set system. The resulting demultiplexed data is spectrum-spread by the MODEM circuit 359 and D/A and frequency converted by the transmission/reception circuit 364 for transmission over the antenna 305.

In the data communication mode of the digital portable telephone set fitted with a camera 301, as when receiving the data of a moving picture file linked to e.g., a simple home page, the signals received over the antenna 305 from a base station are spectrum-despread in the MODEM circuit 359 to produce multiplexed data which is then sent to the demultiplexer 358.

The demultiplexer 358 separates the multiplexed data into encoded image data and speech data, which then are transmitted over the synchronization bus 362 to the image decoder 357 and to the speech codec 360, respectively.

The image decoder 357 decodes the encoded image data in accordance with the decoding system corresponding to the pre-set encoding system, such as MPEG2 or MPEG4, to generate reproduced moving picture data, which is furnished through the LCD controller 356 to the liquid crystal display 309. This enables the digital portable telephone set fitted with a camera 301 to display moving picture data contained in a moving picture file linked to the simple home page.

Simultaneously, the speech codec 360 converts the speech data into analog speech signals, which are sent to the loudspeaker 308. This reproduces the speech data in the digital portable telephone set fitted with a camera 301.

In this case, as in the case of the E-mail, the digital portable telephone set fitted with a camera 301 is able to record data linked to e.g., a received simple home page by user actuation through the storage reproducing unit 363 in the memory stick 311.

The present invention is not limited of the notebook personal computer 1 or to the display unit 302, but may be applied comprehensively to a terminal device, e.g., PDA or PHS (Personal Handyphone System) or to a car navigation system displaying an image by LCD.

1. A flexible substrate comprising:
a connector connected to a plurality of wirings and having a plurality of electrically conducting terminals; and
a shorting wiring interconnected for connecting to one of said plural electrically conducting terminals in said connector and for shorting to the other electrically conducting terminals.

2. The flexible substrate according to claim 1 wherein a hole is provided in a site surrounded by said connector and said shorting wiring.

3. The flexible substrate according to claim 1 wherein a pair of electrically conducting portions are provided adjacent to said shorting wiring.

4. The flexible substrate according to claim 2 wherein a pair of electrically conducting portions provided adjacent to said shorting wiring are provided so as to be closer to said connector than to said hole.

5. The flexible substrate according to claim 4 wherein a plurality of shorting wirings are further provided without interconnecting electrically conducting terminals in superposition.

6. The flexible substrate according to claim 5 wherein a second connector is provided at the opposite end of said wiring connecting to said connector.

7. An information processing apparatus including display means for making desired demonstration and a display control circuit for controlling said display means, said apparatus comprising:
a flexible substrate including a connector connected to a plurality of wirings and having a plurality of electrically conducting terminals, and a shorting wiring interconnected for connecting to one of said plural electrically conducting terminals in said connector and for shorting to the other electrically conducting terminals; and
discriminating means for discriminating the sorts of said display means on detecting the electrically conducting state of said shorting wiring;
said display control circuit performing display control depending on the sort discriminated by said discriminating means.

8. The information processing apparatus according to claim 7 further comprising:
a second connector provided at the other end of the wiring connecting to said connector; and
a cable connecting said second connector to said display means.
